(19) United States
(12) Patent Application Publication
(10) Pub. No.: US 2015/0126017 A1
(43) Pub. Date: May 7, 2015

(54) SYSTEMS AND METHODS FOR ULTRASONICALLY CLEAVING A BONDED WAFER PAIR

(71) Applicant: SunEdison Semiconductor Limited (UEN201334164H), Singapore (SG)

(72) Inventor: Anca Stefanescu, St. Charles, MO (US)

(21) Appl. No.: 14/597,946

(22) Filed: Jan. 15, 2015

Related U.S. Application Data
(62) Division of application No. 13/432,326, filed on Mar. 28, 2012.
(60) Provisional application No. 61/468,425, filed on Mar. 28, 2011.

(51) Int. Cl. H01L 21/84; H01L 21/762

(52) U.S. Cl. CPC H01L 21/84; H01L 21/76254
USPC 438/463

(57) ABSTRACT

Methods for the ultrasonic cleaving of bonded wafer pairs include positioning the bonded wafer pair in a wafer holder disposed in a tank containing a volume of liquid and ultrasonically agitating the volume of liquid in the tank with an ultrasonic agitator. The ultrasonic agitation of the volume of liquid cleaves the bonded wafer pair into a handle wafer and a silicon-on-insulator wafer.

### CROSS-REFERENCE TO RELATED APPLICATIONS

This application is a divisional application of U.S. patent application Ser. No. 13/432,326 filed Mar. 28, 2012, which claims priority to U.S. Provisional Patent Application No. 61/468,425 filed Mar. 28, 2011, the entire disclosures of which are hereby incorporated by reference in their entirety.

### FIELD

This disclosure generally relates to systems and methods for cleaving a bonded wafer pair and, more specifically, to ultrasonically cleaving a bonded wafer pair submerged in a liquid bath.

### BACKGROUND

Semiconductor wafers are generally prepared from a single crystal ingot (e.g., a silicon ingot) which is trimmed and ground to have one or more flats or notches for proper orientation of the wafer in subsequent procedures. The ingot is then sliced into individual wafers. While reference will be made herein to semiconductor wafers constructed from silicon, other materials may be used as well, such as germanium or gallium arsenide.

One type of wafer is a silicon-on-insulator (SOI) wafer. An SOI wafer includes a thin layer of silicon atop an insulating layer (i.e., an oxide layer), which is in turn disposed on a silicon substrate. A silicon-on-insulator wafer is a type of silicon-on-insulator structure.

An example process of making an SOI wafer includes depositing a layer of oxide on a polished front surface of a donor wafer. Ions (e.g., hydrogen ions or a combination of hydrogen and helium ions) are implanted at a specified depth beneath the front surface of the donor wafer. The implanted ions form a cleave plane in the donor wafer at the specified depth at which they were implanted. The surface of the donor wafer is cleaned to remove organic compounds deposited on the wafer during the implantation process.

The front surface of the donor wafer is then bonded to a handle wafer to form a bonded wafer through a hydrophilic bonding process. The donor wafer and handle wafer are bonded together by exposing the surfaces of the wafers to plasma containing, for example, oxygen or nitrogen. Exposure to the plasma modifies the structure of the surfaces in a process often referred to as surface activation. The wafers are then pressed together and a bond is formed therebetween. This bond is relatively weak, and must be strengthened before further processing can occur.

In some processes, the hydrophilic bond between the donor wafer and handle wafer (i.e., a bonded wafer) is strengthened by heating or annealing the bonded wafer pair at temperatures between approximately 300° C. and 500° C. The elevated temperatures cause the formation of covalent bonds between the adjoining surfaces of the donor wafer and the handle wafer, thus solidifying the bond between the donor wafer and the handle wafer. Concurrently with the heating or annealing of the bonded wafer, the particles or ions earlier implanted in the donor wafer weaken the cleave plane. A portion of the donor wafer is then separated (i.e., cleaved) along the cleave plane from the bonded wafer to form the SOI wafer.

The bonded wafer is first placed in a fixture in which mechanical force is applied perpendicular to the opposing sides of the bonded wafer in order to pull a portion of the donor wafer apart from the bonded wafer. According to some methods, suction cups are utilized to apply the mechanical force. The separation of the portion of the donor wafer is initiated by applying a mechanical wedge at the edge of the bonded wafer pair at the interface between the donor wafer and the handle wafer. The application of the mechanical force initiates propagation of a cleave along the cleave plane. The mechanical force applied by the suction cups then pulls a portion of the donor wafer away from the bonded wafer, thus forming an SOI wafer. The portion of the donor wafer remaining atop the oxide layer is referred to as a transferred layer.

The resulting SOI wafer comprises a thin layer of silicon (i.e., the transferred layer) disposed atop the oxide layer and the handle wafer. The thickness of the transferred layer may be non-uniform and radially asymmetric. The transferred layer may also have a non-uniform roughness. This non-uniform and asymmetric thickness and roughness of the transferred layer may be the result of the cleave propagating at varying speeds and/or the mechanical force applied by the suction cups. Additional processing is thus required to reduce the variation in thickness of the transferred layer and/or smooth this layer. These additional processing steps are both time-consuming and costly.

Thus, there remains a need for a system and method for cleaving a bonded wafer pair that results in the SOI wafer having a transferred layer with a relatively uniform and radially symmetric thickness and roughness.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

One aspect of the present disclosure is a system for ultrasonically cleaving a bonded wafer pair having a first face and a second face. The system comprises a tank for containing a volume of liquid, a wafer boat and an ultrasonic agitator. The wafer boat has at least one recess formed therein for receiving the bonded wafer pair. The recess has a pair of opposing, spaced-apart sidewalls disposed at an angle from a vertical axis. The ultrasonic agitator is configured to ultrasonically agitate the volume of liquid. The ultrasonic agitation of the volume of liquid results in the cleaving of the bonded wafer pair.

Another aspect of the present disclosure is a method of ultrasonically cleaving a bonded wafer pair. The method comprises positioning the bonded wafer pair in a wafer holder such as a wafer boat disposed in a tank containing a volume of liquid, ultrasonically agitating the volume of liquid in the tank with an ultrasonic agitator. The ultrasonic agitation of the volume of liquid cleaves the bonded wafer pair into a handle wafer and a silicon-on-insulator wafer.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a cross-sectional view of an embodiment of a system for ultrasonically cleaving a bonded wafer pair;

FIG. 2 is an enlarged view of a portion of FIG. 1;

FIG. 3 is a cross-sectional view of the system of FIG. 1 after the wafers have been cleaved;

FIG. 4 is an enlarged view of a portion of FIG. 3; and

FIG. 5 is a cross-sectional view of another embodiment of a system for ultrasonically cleaving a bonded wafer pair.

Like reference symbols in the various drawings indicate like elements.

### DETAILED DESCRIPTION

The embodiments described herein generally relate to systems and methods for ultrasonically cleaving a bonded wafer pair. The systems and methods cleave (i.e., separate) a portion of a donor wafer along a cleave plane from the bonded wafer pair to form a silicon-on-insulator (SOI) wafer. While reference is made herein to use of the systems and method in cleaving silicon-on-insulator structures, the systems and methods can also be used to cleave or separate layers in other structures, such as silicon-on-sapphire structures.

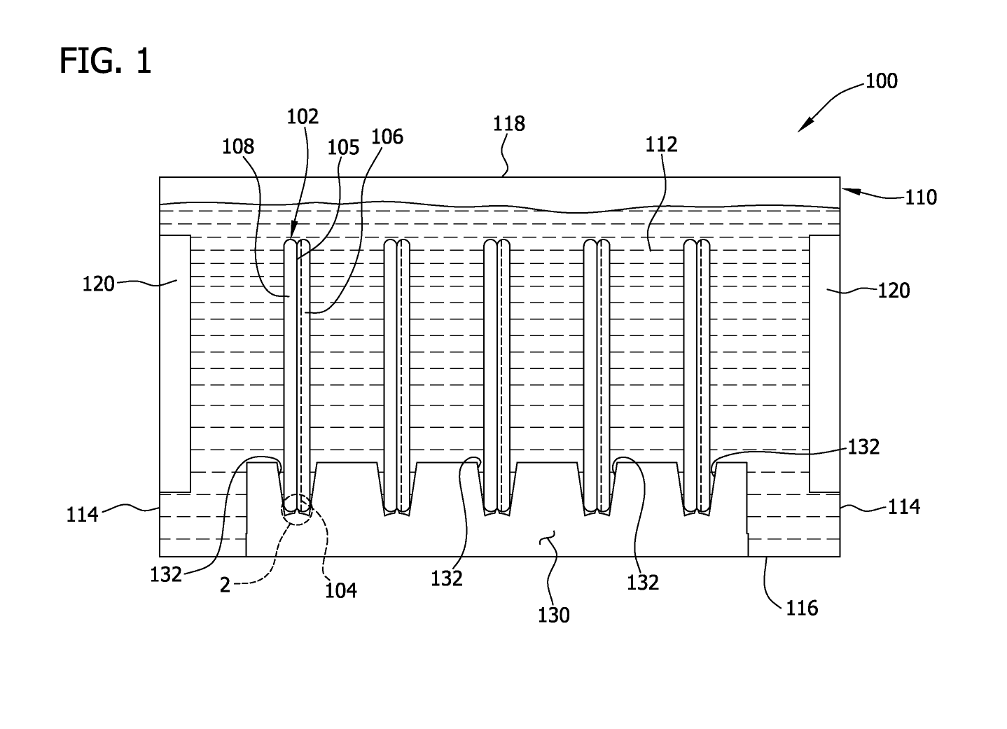

FIG. 1 depicts a system 100 for ultrasonically cleaving bonded wafer pairs 102 along respective cleave planes 104. The bonded wafer pairs 102 include a donor wafer 106 bonded to a handle wafer 108 along a bond interface 105. Only one bonded wafer pair 102 is identified with reference numerals in the Figures, although the other bonded wafer pairs have the same or substantially similar features.

Helium and/or hydrogen ions are implanted in the donor wafer 106 at a specified depth and concentration to form the cleave plane 104 beneath the surface of the donor wafer. According to one embodiment, the helium ions are implanted at a density of about 1.1e16 ions/cm² to about 1.2e16 ions/cm². Hydrogen ions are implanted at a density of about 0.55e16 ions/cm² to about 0.75e16 ions/cm².

The system 100 includes a tank 110 filled with a liquid 112. The liquid 112 may be ozonated de-ionized water for reasons described in greater detail below. The tank 110 is a rectangular structure having opposing vertical walls 114 connected to a base 116 and an open top portion 118. In other embodiments, the tank 110 can be differently shaped and/or have a closed top portion 118. The tank 110 is constructed from any suitable material that will not contaminate the liquid 112. For example, the tank 110 may be constructed from stainless steel or a suitably non-reactive plastic material.

Two ultrasonic agitators 120 are positioned in the tank 110 in the example embodiment. The ultrasonic agitators 120 are connected to opposing walls 114 of the tank 110 by any suitable fastener system. In other embodiments, different numbers of ultrasonic agitators 120 may be used and/or positioned differently with respect to the tank 110. For example, a single ultrasonic agitator 120 may be positioned adjacent to the base 116 of the tank 110. Moreover, ultrasonic agitators 120 may be positioned adjacent to and externally of the tank 110. In the example embodiment, the ultrasonic agitators 120 have power ratings of greater than about 100 watts, for example, about 600 watts up to about 2400 watts. Moreover, the ultrasonic agitators may vibrate at frequencies between about 27 kHz to about 40 kHz in the example embodiment.

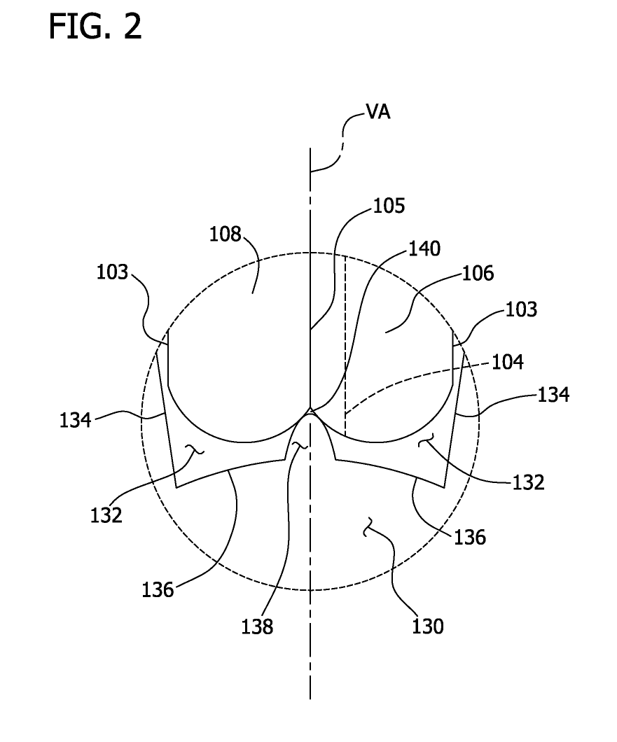

A wafer boat 130 (broadly, a wafer holder) is positioned internally of the tank to hold bonded wafer pairs 102. As best seen in FIG. 2, the wafer boat 130 has a plurality of recesses 132 formed therein, each of which receives an individual wafer pair 102 therein. The recesses 132 each have a pair of opposing, spaced-apart sidewalls 134 connected by an arcuate-shaped bottom surface 136.

A ridge 138 is disposed on the bottom surface 136 generally equidistant from the sidewalls 134. In the example embodiment, the ridge 138 has an arcuate-shaped profile, while in other embodiments the ridge may be differently shaped. During use, a portion 140 of the edge of the bonded wafer pair 102 adjacent the cleave plane 104 rests on the ridge 138 prior to cleaving of the wafer. This portion 140 of the wafer 102 has a slight indentation formed therein and the ridge 138 is sized such that at least a portion of the ridge is received within the indentation. In the example embodiment, only this portion 140 of the wafer 102 contacts the ridge 138.

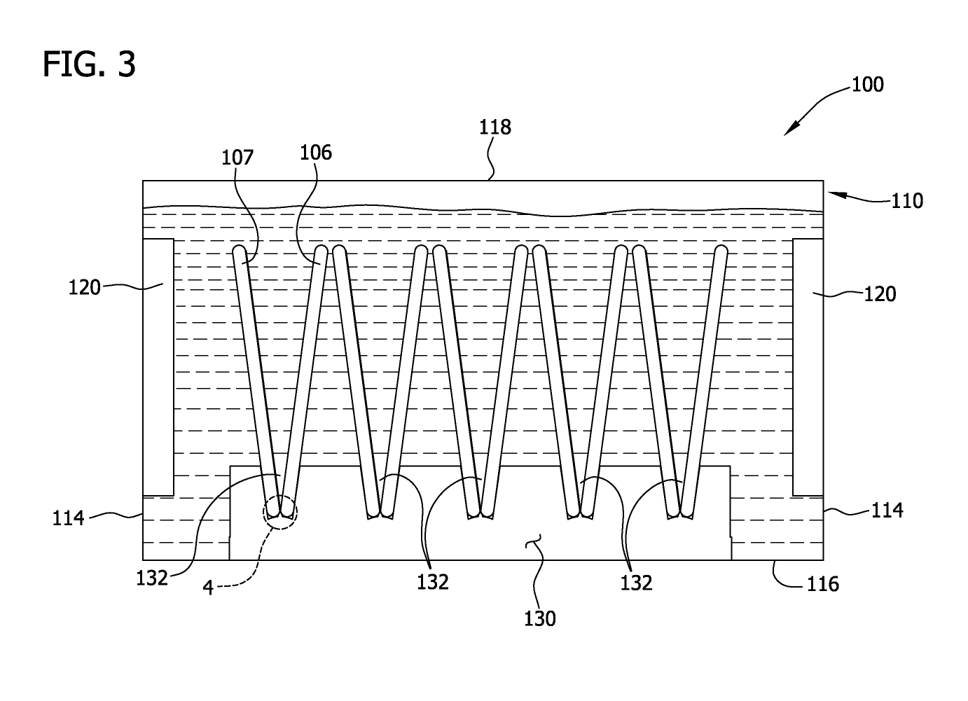

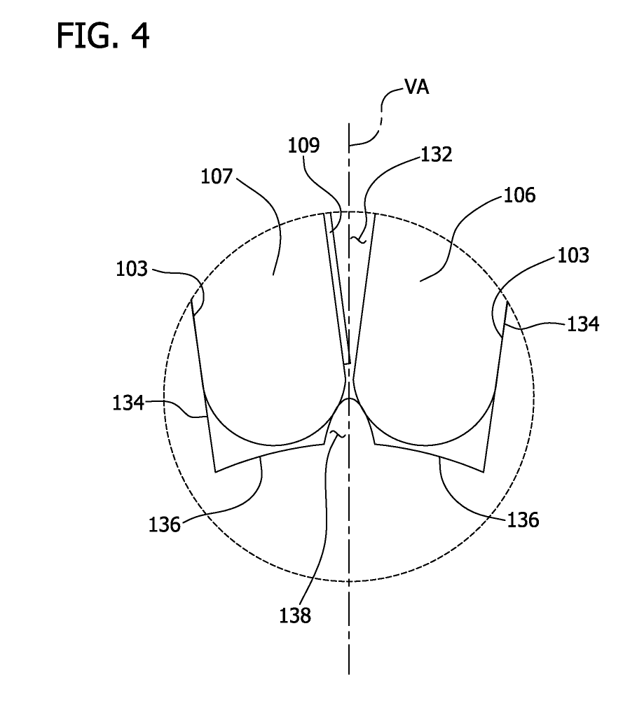

The sidewalls 134 of the recesses 132 are each disposed at angle from a vertical axis VA. The angle for each of the sidewalls 134 is the same in this embodiment, while in others the angles may differ from each other. The angle is such that the opposing surfaces 103 of the wafer 102 do not contact the sidewalls 134 prior to the wafer being cleaved. In the example embodiment, the angle may be between 1 and 30 degrees from the vertical axis. Moreover, the sidewalls 134 of each recess 132 are spaced from each other such that after the wafer 102 has been cleaved the handle wafer 108 and the donor wafer 106 do not contact each other (FIGS. 3 and 4). Instead, the donor wafer 106 and the handle wafer 108 rest against respective sidewalls 134 of the recess 132.

The sidewalls 134 are shown in the FIGS. 1-4 as extending upward from the bottom surface 136 to a height that is about 20% of that of the diameter of the wafer 102. In other embodiments, the height of the sidewalls 134 may be greater than or less than about 20% of the diameter of the wafer 102.

The wafer boat 130 is constructed from material which will not contaminate either the liquid 112 in the tank 110 or the wafers 102 disposed in the tank. In some embodiments, the wafer boat 130 is constructed from a composite material coated with polytetrafluoroethylene (PTFE) or made entirely or partially out of PTFE.

The wafer boat 130 may be configured such that it has a natural frequency that is different than the frequency at which the ultrasonic agitators 120 vibrate the liquid 112. In other embodiments, however, the natural frequency of the wafer boat 130 is the same as the frequency at which the agitators 120 vibrate the liquid 112.

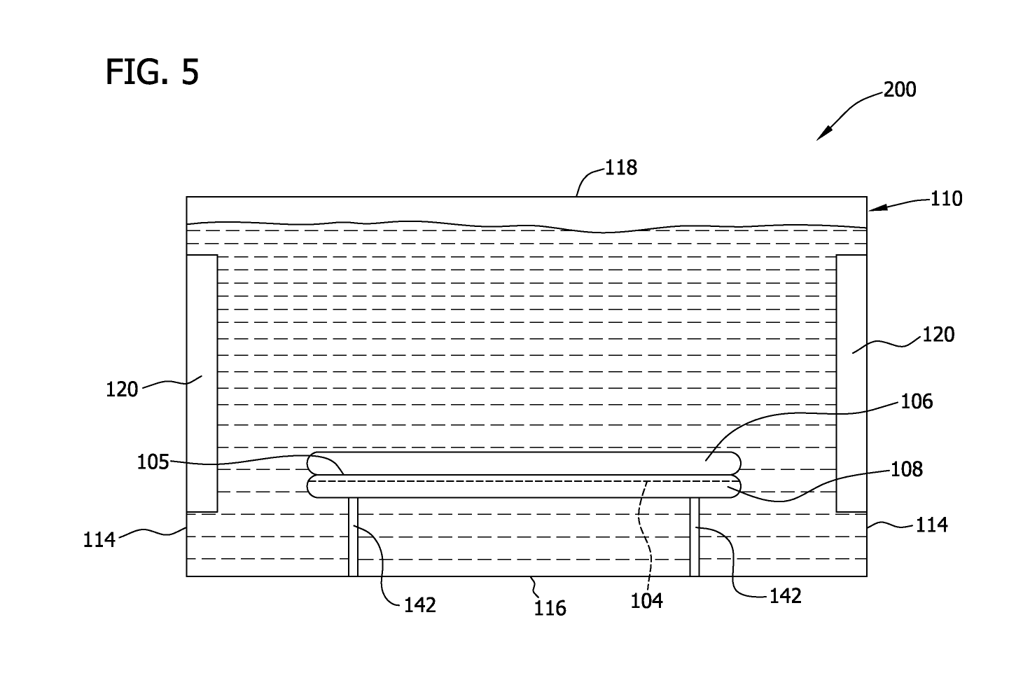

FIG. 5 shows another embodiment of a system 200 similar to the system 100 that positions the bonded wafer pair 102 in the tank 110 in a substantially horizontal configuration. The bonded wafer pair 102 is supported by posts 142 (a wafer holder) connected to the base 116 of the tank 110. Any number of posts 142 may be used in other embodiments. Moreover, while the handle wafer 108 is in contact with the posts 142, the donor wafer 106 may instead contact the posts. The other features of the system 200 are substantially similar to or the same as those of the system 100 and like reference numerals are used to refer to like elements.

In operation, bonded wafer pairs 102 are placed in the tank 110. In the system 100, the wafers 102 are placed in the recesses 132 of the wafer boat 130, while in the system 200 the wafer is placed atop the posts 142. The tank 110 may then be filled with a volume of liquid 112, or alternatively the tank may have been previously filled. The volume of liquid 112 is then ultrasonically agitated (i.e., vibrated) by the ultrasonic agitators 120. The ultrasonic agitation continues for a period of time (e.g., 30 seconds to five minutes) at a predetermined frequency.

The ultrasonic agitation of the liquid 120 results in the uniform ultrasonic vibration of the bonded wafer pair 102. Substantially the entire wafer 102 is subject to vibrations of the same frequency and intensity. These vibrations in turn cleave the bonded wafer pair 102 along the cleave plane 104 into an SOI wafer 107 and the remaining portion of the donor wafer 106. FIG. 3 shows the donor wafer 106 and the SOI wafer 107 after the bonded wafer pairs 102 have been cleaved by ultrasonic agitation. As shown in the enlarged view of SOI wafer 107 in FIG. 4, the portion of the donor wafer 106 remaining atop SOI wafer is referred to as a transferred layer 109. The transferred layer 109 is omitted from FIG. 3 for clarity.

Because the bonded wafer pair 102 is uniformly vibrated in the systems 100, 200, the wafer pair separates symmetrically along the cleave plane 104. In contrast, prior art systems necessarily separated bonded wafer pairs asymmetrically as the cleave was initiated at a specific point (i.e., by the suction cups and/or blade) and propagated along the cleave plane from this point.

Without being bound to any particular theory, it is believed that the symmetric propagation of the cleave in the systems 100, 200 results in significant reduction in non-uniform thickness and/or roughness surface defects on the transferred layer 109 of the SOI wafer 107. This reduction significantly reduces the time required for further downstream wafer processing. Moreover, these downstream processes are symmetric in that they are applied evenly across the surface of the wafer. Symmetric processes cannot efficiently repair the asymmetric defects caused by prior art methods used to form SOI wafers. For example, a smoothing process is a symmetric process that cannot correct asymmetric defects. Wafers processed according to these prior art methods had functional or visual defects that would not meet some customer specifications, resulting in wafer rejection and yield loss.

Cleaving the bonded wafer pairs 102 in the volume of liquid 112 significantly reduces or eliminates contamination of the cleaved surface of the SOI wafer 107 after the wafers have been cleaved. Prior art methods cleaved wafers on a separate device exposed to air (the ambient environment). The as-cleaved surface of the SOI wafer is highly reactive and traps particulate, metallic, and organic contaminants present in the ambient environment. Such contamination causes light particle defects (LPDs), film thickness and roughness non-uniformities and haze. This contamination negatively impacts the final SOI wafer quality.

The liquid 112 in the tank 110 is ozonated such that any organic compounds within the liquid are eliminated and do not contaminate the cleaved surface. The liquid 112 can also contain additives such that a post-cleaving cleaning step is performed while the SOI wafer 107 is still submerged in the liquid. Performing the cleaning step while the SOI wafer 107 is submerged in the liquid 112, rather than after removing the SOI wafer from the liquid, prevents contamination of the cleaved surface by the surrounding environment. Moreover, performing the cleaning step while the SOI wafer 107 is submerged in the liquid 112 also reduces the amount of time (cycle time) and cost required to manufacture the SOI wafer.

While the present has been described in terms of various specific embodiments, it will be recognized that the present can be practiced with modification within the spirit and scope of the claims.

When introducing elements of the present disclosure or the embodiments thereof, the articles “a”, “an”, “the” and “said” are intended to mean that there are one or more of the elements. The terms “comprising”, “including” and “having” are intended to be inclusive and mean that there may be additional elements other than the listed elements. The use of terms indicating a particular orientation (e.g., “top”, “bottom”, “side”, etc.) is for convenience of description and does not require any particular orientation of the item described.

As various changes could be made in the above constructions and methods without departing from the scope of the invention, it is intended that all matter contained in the above description and shown in the accompanying drawings shall be interpreted as illustrative and not in a limiting sense.

What is claimed is:

1. A method of ultrasonically cleaving a bonded wafer pair comprising:
positioning the bonded wafer pair in a wafer holder disposed in a tank containing a volume of liquid;
ultrasonically agitating the volume of liquid in the tank with an ultrasonic agitator, wherein the ultrasonic agitation of the volume of liquid cleaves the bonded wafer pair into a handle wafer and a silicon-on-insulator wafer.

2. The method of claim 1 wherein positioning the bonded wafer pair includes placing the bonded wafer pair in a recess of a wafer boat.

3. The method of claim 2 wherein the positioning further includes positioning an indentation of the bonded wafer pair over a ridge in the wafer boat.

4. The method of claim 3 further comprising using the ridge to facilitate cleaving the bonded wafer pair.

5. The method of claim 1 wherein the bonded wafer pair is placed in the tank horizontally on posts.

6. The method of claim 1 further comprising filling the tank with an ozonated liquid.

7. The method of claim 6 wherein the tank is filled such that the entirety of the bonded wafer pair is submerged in the liquid.

8. The method of claim 1 wherein the ultrasonic agitation includes uniformly vibrating the bonded wafer pair at the same frequency and intensity to cause symmetric separation of the of the wafer pair.

9. The method of claim 1 wherein the ultrasonic agitation is performed by multiple agitators vibrating at frequencies between about 27 kHz to about 40 kHz.

10. The method of claim 1 wherein the positioning includes positioning a plurality of bonded wafer pairs in the wafer holder.

11. The method of claim 1, wherein the bonded wafer pair has a cleave plane formed by ion implantation, wherein the ultrasonic agitation cleaves the bonded wafer pair along the cleave plane.

12. The method of claim 1, wherein ultrasonically agitating the volume of liquid includes operating the ultrasonic agitator at a power of between about 600 watts and about 2400 watts.

13. The method of claim 1, wherein ultrasonically agitating the volume of liquid includes operating the ultrasonic agitator at a frequency other than a natural frequency of the wafer holder.

14. A method of ultrasonically cleaving a bonded wafer pair mounted in a wafer boat, the method comprising:
positioning the bonded wafer pair in a wafer boat disposed in a tank containing a volume of liquid, including positioning an indentation of the bonded wafer pair in contact with a ridge in the wafer boat;
ultrasonically agitating the volume of liquid in the tank with an ultrasonic agitator, wherein the ultrasonic agitation of the volume of liquid cleaves the bonded wafer pair into a handle wafer and a silicon-on-insulator wafer.

15. The method of claim 14 further comprising using the ridge to facilitate cleaving the bonded wafer pair.

16. The method of claim 14 wherein positioning the bonded wafer pair includes placing the bonded wafer pair in a recess of the wafer boat, the ridge being disposed in the recess.

17. The method of claim 16 further comprising filling the tank with an ozonated liquid.

18. The method of claim 17 wherein the tank is filled such that the entirety of the bonded wafer pair is submerged in the liquid.

19. The method of claim 18 wherein the ultrasonic agitation includes uniformly vibrating the bonded wafer pair at the same frequency and intensity to cause symmetric separation of the of the wafer pair.

20. The method of claim 14 wherein positioning the bonded wafer pair includes positioning a plurality of bonded wafer pairs in the wafer boat.
